(19) United States
(12) Patent Application Publication
(10) Pub. No.: US 2025/0203779 A1
(43) Pub. Date: Jun. 19, 2025

(54) Sensor Apparatus

(71) Applicant: Sumitomo Precision Products Co., Ltd., Amagasaki-shi, Hyogo (JP)

(72) Inventors: Hideyuki DOYAMA, Amagasaki-shi (JP); Ryohei UCHINO, Amagasaki-shi (JP)

(21) Appl. No.: 18/851,766

(22) PCT Filed: Mar. 8, 2023
(86) PCT No.: PCT/JP2023/008838

§ 371 Date: Sep. 27, 2024

(30) Foreign Application Priority Data
Mar. 28, 2022 (JP) 2022-052373

(51) Int. Cl. H05K 1/18; H05K 1/14

(52) U.S. Cl. CPC H05K 1/181; H05K 1/144; H05K 2201/042; H05K 2201/10151; H05K 2201/10371

(57) ABSTRACT

A sensor apparatus (100) according to this invention includes an interior space accommodating a sensor (2z), a sensor arrangement part (1), a first board (6z) and a second board (5) and being defined by a shielding cover (4) and a base (3), and the sensor apparatus (100) is attached to another apparatus (200) with a bottom of the base (3) being in tight contact with the another apparatus (200).

### TECHNICAL FIELD

The present invention relates to a sensor apparatus, and particularly to a sensor apparatus including a sensor arrangement part to which a sensor is provided.

### BACKGROUND ART

Sensor apparatuses including a sensor arrangement part to which a sensor is provided are known in the art. Such a sensor apparatus is disclosed in Japanese Patent Laid-Open Publication No. JP 2021-56197, for example.

Japanese Patent Laid-Open Publication No. JP 2021-56197 discloses an inertial measurement apparatus (sensor apparatus) including an inertial sensor and a case (sensor arrangement part) in which the inertial sensor is arranged. In the above Japanese Patent Laid-Open Publication No. JP 2021-56197, a first board including a processor performing processing based on detection information from the inertial sensor is arranged on an upper surface of the case. In addition, a second board including a display for displaying a measurement result is provided in the Japanese Patent Laid-Open Publication No. JP 2021-56197. The second board is stacked above the first board. Specifically, the second board is supported by a support part. The support part is arranged on the upper surface of the first board.

### PRIOR ART

### Patent Document Patent Document 1: Japanese Patent Laid-Open Publication No. JP 2021-56197

### SUMMARY OF THE INVENTION

### Problems to Be Solved by the Invention

The inertial measurement apparatus (sensor apparatus) as disclosed in Japanese Patent Laid-Open Publication No. JP 2021-56197 is accommodated in space enclosed between a box-shaped cover and a base part covering an opening of the box-shaped cover. In such space, even if the space is not sealed, air flow is unlikely to flow so that heat generated from the first board and the second board of the sensor apparatus is unlikely to escape. Also, the space inside the cover is brought in a vacuum during use in some cases, and it is more difficult to dissipate heat generated from the first board and the second board through air in such a case.

The present invention is intended to solve the above problem, and one object of the present invention is to provide a sensor apparatus capable of easily dissipating heat generated from a first board and a second board even in a case in which the first board and the second board are arranged in a cover.

### Means for Solving the Problems

In order to attain the aforementioned object, a sensor apparatus according to an aspect of the present invention includes a sensor; a sensor arrangement part in which the sensor is arranged; a first board provided to the sensor arrangement part; a second board arranged parallel to the first board to be stacked above the first board; a shielding cover provided to cover the sensor arrangement part and including at least one opening; and a base being in tight contact with the sensor arrangement part and fixing the sensor arrangement part, wherein the first board and the second board are directly attached to the sensor arrangement part, an interior space accommodating the sensor, the sensor arrangement part, the first board and the second board is defined by the shielding cover and the base by fixing the shielding cover to the base with the opening of the shielding cover facing the base, and the sensor apparatus is attached to another apparatus with a bottom of the base being in tight contact with the another apparatus.

In the sensor apparatus according to the aspect of this invention, as discussed above, the first board and the second board are directly attached to the sensor arrangement part. Accordingly, heat generated from the first board and the second board is directly dissipated to the sensor arrangement part. In addition, the heat dissipated to the sensor arrangement part is then dissipated to the another apparatus through the base. Consequently, it is possible to easily dissipate the heat generated from the first board and the second board even in a case in which the first board and the second board are arranged in the cover.

In the sensor apparatus according to the aforementioned aspect, it is preferable that the sensor arrangement part includes a predetermined surface having a projected area not smaller than an area of the second board as viewed in a direction perpendicular to a surface of the second board and flatly extending; a plurality of first protrusions that are arranged to protrude from the predetermined surface and to which the first board is attached, and a plurality of second protrusions that are arranged to protrude from the predetermined surface and to which the second board is attached; and first crest surfaces are formed on crests of the plurality of first protrusions to be in contact with the first board; the first crest surfaces are independent of each other; second crest surfaces are formed on crests of the plurality of second protrusions to be in contact with the second board; the second crest surfaces are independent of each other; the first crest surfaces and the second crest surfaces are parallel to the predetermined surface, and are parallel to each other; and the second protrusions have a protrusion amount from the predetermined surface greater than the first protrusions. Accordingly, since the first board is attached to the first protrusions, which are arranged to protrude from the predetermined surface, a gap is created between the first board and the predetermined surface. As a result, it is possible to prevent contact between the first board and the predetermined surface even when the first board is deformed due to vibration, and the like. Also, since the second board is attached to the second protrusions, which have a protrusion amount from the predetermined surface greater than a protrusion amount of the first protrusion, the first board and the second board can be easily stacked.

In this configuration, it is preferable that the first board includes cut-out parts avoiding the second protrusions. Accordingly, it is possible avoid interference between the first board and the second protrusions. As a result, it is possible to prevent the sensor apparatus (sensor arrangement part) from becoming larger dissimilar to a case in which the second protrusions are arranged outside the first board without the cut-out parts.

In the sensor apparatus in which the first board includes the cut-out parts, it is preferable that the sensor arrangement part and the first protrusion includes metal; that the first board includes a multilayer board including at least a wiring pattern or a through hole; and that the first board includes attachment parts that are attached to the first crest surfaces of the first protrusions and arranged at positions avoiding at least the wiring pattern or the through-hole. Accordingly, it is possible to prevent a short circuit between the sensor arrangement part and at least the wiring pattern or the through-hole.

In this configuration, it is preferable that the first board includes a grounding pattern electrically connected to the sensor arrangement part to have a common potential to the sensor arrangement part; and the attachment parts of the first board are arranged in parts of the first board in which the grounding pattern is arranged. Accordingly, since both the sensor arrangement part and the grounding pattern are metal, it is possible to efficiently dissipate heat from the first board to the sensor arrangement part.

### Effect of the Invention

According to the present invention, it is possible to easily dissipate heat generated from a first board and a second board even in a case in which the first board and the second board are arranged in the cover.

### BRIEF DESCRIPTION OF THE DRAWINGS

FIG. 1 is an exploded perspective view entirely showing a sensor apparatus according to one embodiment.

FIG. 2 is an exploded perspective view showing a sensor mount, and control and power supply boards according to the one embodiment.

FIG. 3 is an exploded perspective view showing the sensor mount, gyroscopes, and plates according to the one embodiment.

FIG. 4 is a perspective view of the sensor mount according to the one embodiment as diagonally viewed from a lower side.

FIG. 5 is a block diagram showing a configuration of a sensor apparatus according to the one embodiment.

FIG. 6 is a schematic sectional view showing a relation between a connection wiring part and a cut-out part in the one embodiment.

FIG. 7 is a perspective view showing a configuration of the gyroscope according to the one embodiment.

### Modes for Carrying Out the Invention

Embodiments according to the present invention will be described with reference to the drawings.

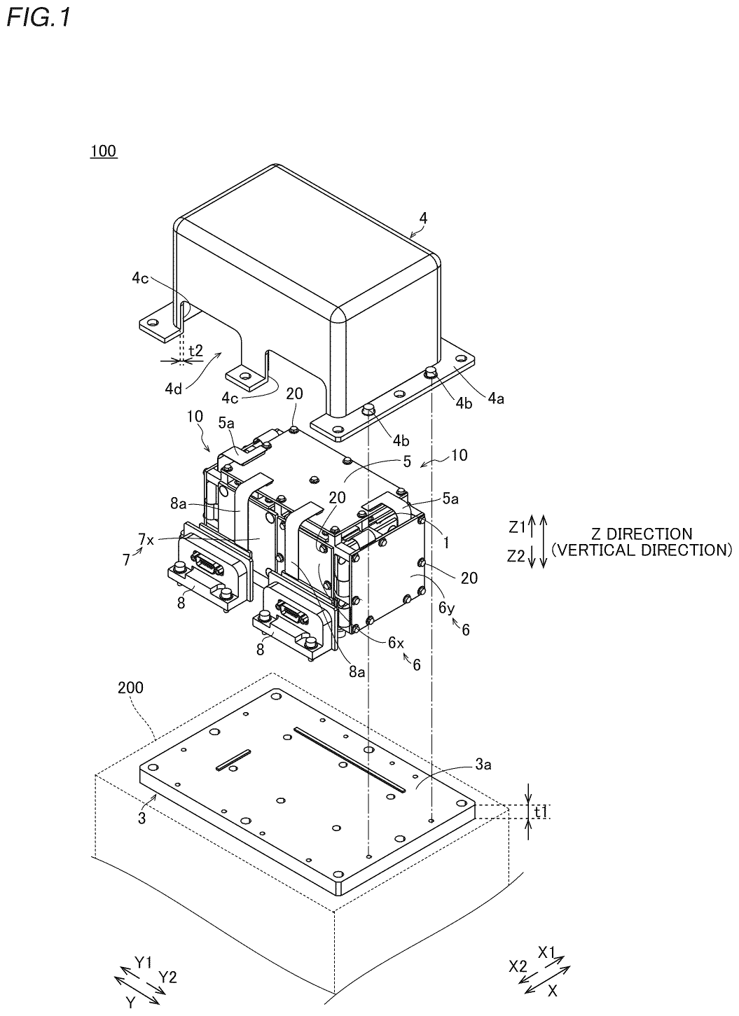

A sensor apparatus 100 according to one embodiment is first described with reference to FIGS. 1 to 7.

### Entire Configuration of Sensor Apparatus

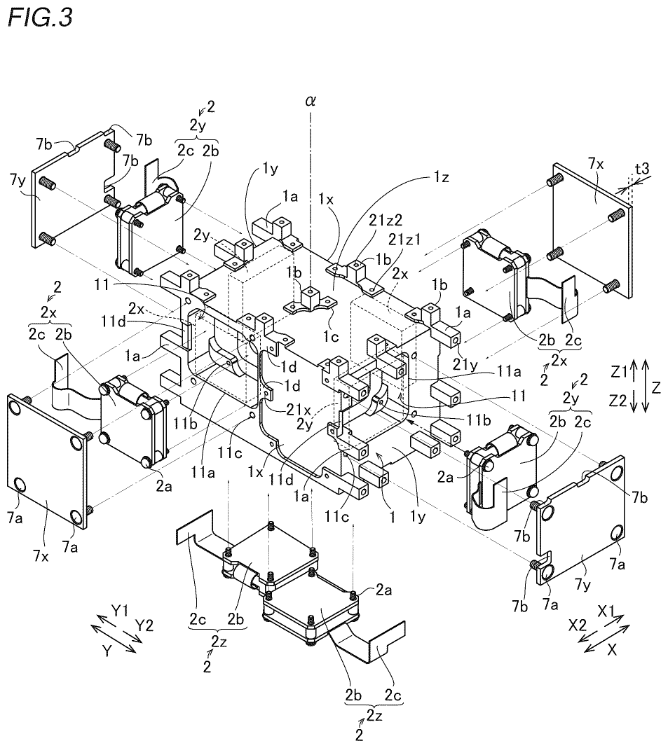

As shown in FIG. 1, the sensor apparatus 100 includes a sensor mount 1, gyroscopes 2 (see FIG. 3), a base 3, a cover 4, a power supply board 5, control boards 6 and plates 7. Here, the sensor mount 1 and the gyroscope 2 are an example of a “sensor arrangement part” and an example of a “sensor”, respectively, in the claims. Also, the power supply board 5 is an example of a “second board” in the claims. Also, the cover 4 is an example of a “shielding cover” in the claims.

Two connectors 8 for connecting to the power supply board 5 to an external power supply (not shown) and for transmitting/receiving signals are attached to the sensor mount 1. The connectors 8 are connected to the power supply board 5 through flexible cables 8a. The flexible cables 8a are provided to the sensor apparatus 100 with being bent. Any of FPC (Flexible printed Circuit) and FFC (Flexible Flat Cable) can be used as the flexible cables 8a.

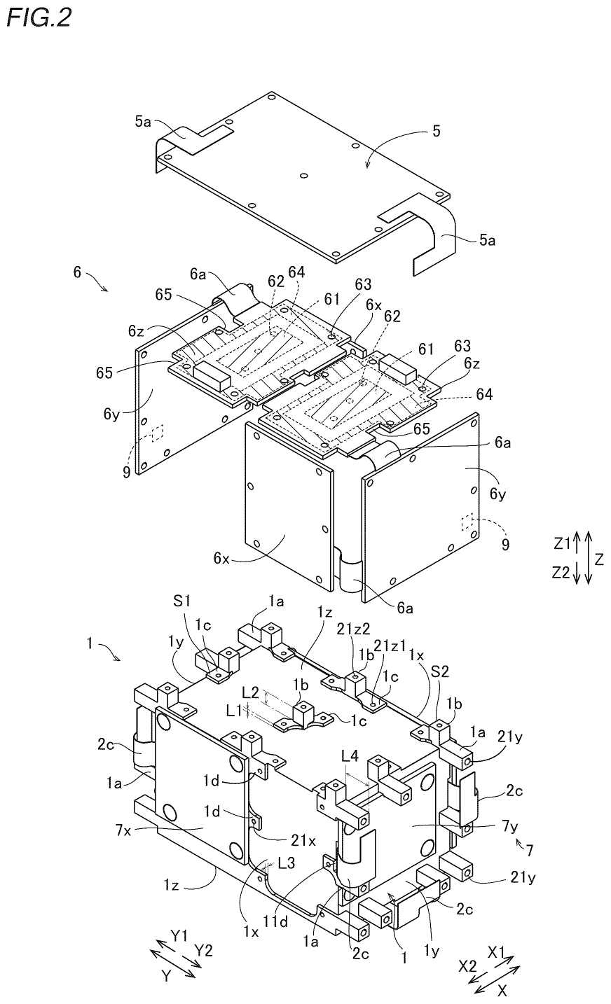

The sensor mount 1 has a rectangular parallelepiped shape, as shown in FIG. 2. Also, the sensor mount 1 includes a pair of X-axis surfaces 1x, which extend perpendicular to an X axis, a pair of Y-axis surfaces 1y, which extend perpendicular to a Y axis, and a pair of Z-axis surfaces 1z, which extend perpendicular to a Z axis. Also, the Z-axis surface 1z on a Z2 side of the pair of Z-axis surfaces 1z is an example of a “predetermined surface” in the claims. Here, in this embodiment, the Z axis is an axis that extends in a vertical direction.

In this embodiment, the Z-axis surface 1z has a projected area not smaller than an area of the power supply board 5 as viewed in a direction (Z direction) perpendicular to a surface of the power supply board 5. In other words, the area of the Z-axis surface 1z is not smaller than the area of the power supply board 5.

In this embodiment, the sensor mount 1 includes X-axis protrusions 1d which are arranged to protrude from the X-axis surfaces 1x and to which X axis control boards 6x described later are attached. A plurality of X-axis protrusions 1d are arranged on the X-axis surface 1x. The plurality of X-axis protrusions 1d are arranged in outer peripheral edges of the X-axis surface 1x, which has a roughly quadrangular shape. Each of the plurality of X-axis protrusions 1d has a hole 21x into which a screw 20 (see FIG. 1) is screwed to attach the X-axis control board 6x to the X-axis protrusion 1d. The X-axis protrusions 1d are arranged on each of the pair of X-axis surfaces 1x. The X-axis protrusions 1d are integrally formed with the sensor mount 1, and the X-axis protrusions 1d are formed of metal.

In this embodiment, the sensor mount 1 includes Y-axis protrusions 1a which are arranged to protrude from the Y-axis surfaces 1y and to which Y-axis control boards 6y described later are attached. A plurality of Y-axis protrusions 1a are arranged on the Y-axis surface 1y. The plurality of Y-axis protrusions 1a are arranged in outer peripheral edges of the Y-axis surface 1y, which has a roughly quadrangular shape. Each of the plurality of Y-axis protrusions 1a has a hole 21y into which the screw 20 (see FIG. 1) is screwed to attach the Y-axis control board 6y to the Y-axis protrusion 1a. The Y-axis protrusions 1a are arranged on each of the pair of Y-axis surfaces 1y. The Y-axis protrusions 1a are integrally formed with the sensor mount 1, and the Y-axis protrusions 1a are formed of metal. The Y-axis protrusions 1a have a prism shape.

In this embodiment, the sensor mount 1 includes Z-axis protrusions 1c which are arranged to protrude from the Z-axis surface 1z on a Z1 side and to which Z-axis control boards 6z described later are attached. A plurality of Z-axis protrusions 1c are arranged on the Z-axis surface 1z. Two or more of the plurality of Z-axis protrusions 1c are arranged in outer peripheral edges of the Z-axis surface 1z, which has a roughly quadrangular shape, and two or more of the plurality of Z-axis protrusions 1c are arranged in a central part of the Z-axis surface 1z. Each of the plurality of Z-axis protrusions 1c has a hole 21z1 into which the screw 20 (see FIG. 1) is screwed to attach the Z-axis control board 6z to the Z-axis protrusion 1c. The Z-axis protrusions 1c are integrally formed with the sensor mount 1, and the Z-axis protrusions 1c are formed of metal. The Z-axis control boards 6z are examples of a “first board” in the claims. The Z-axis protrusions 1c are examples of a “first protrusion” in the claims.

In this embodiment, the sensor mount 1 includes the Z-axis protrusions 1b which are arranged to protrude from the Z-axis surface 1z on a Z1 side and have a protrusion amount L2 greater than a protrusion amount L1 of the Z-axis protrusions 1c from the Z-axis surface 1z, and to which the power supply board 5 is attached. A plurality of Z-axis protrusions 1b are arranged on the Z-axis surface 1z. Two or more of the plurality of Z-axis protrusions 1b are arranged in the outer peripheral edges of the Z-axis surface 1z, which has a roughly quadrangular shape, and one of the plurality of Z-axis protrusions 1b is arranged in the central part of the Z-axis surface 1z. Each of the plurality of Z-axis protrusions 1b has a hole 21z2 into which the screw 20 (see FIG. 1) is screwed to attach the power supply board 5 to the Z-axis protrusion 1b. The Z-axis protrusions 1b are integrally formed with the sensor mount 1, and the Z-axis protrusions 1b are formed of metal. The Z-axis protrusions 1b have a prism shape. The Z-axis protrusions 1b are examples of a “second protrusion” in the claims.

In this embodiment, a plurality of crest surfaces S1 are formed on crests of the plurality of Z-axis protrusions 1c to be in contact with the Z-axis control boards 6z, and the plurality of crest surfaces S1 are independent of each other. In other words, the plurality of crest surfaces S1 are spaced away from each other. A plurality of crest surfaces S2 are formed on crests of the plurality of Z-axis protrusions 1b to be in contact with the power supply board 5, and the plurality of crest surfaces S2 are independent of each other. In other words, the plurality of crest surfaces S2 are spaced away from each other. The crest surfaces S1 and the crest surfaces S2 are parallel to the Z-axis surface 1z, and are parallel to each other. The Z-axis protrusions 1b have a protrusion amount L2 from the Z-axis surface 1z greater than the Z-axis protrusions 1c. The crest surfaces S1 and the crest surfaces S2 are examples of a “first crest surface” and examples of a “second crest surface”, respectively, in the claims.

The protrusion amount L1 of each Z-axis protrusion 1c from the Z-axis surface 1z is substantially the same as a protrusion amount L3 of each X-axis protrusion 1d from the X-axis surface 1x. The protrusion amount L2 of each Z-axis protrusion 1b from the Z-axis surface 1z is smaller than a protrusion amount L4 of each Y-axis protrusion 1a from the Y-axis surface 1y.

The sensor mount 1 is also formed of metal. Specifically, the sensor mount 1 is formed of a non-magnetic metal (e.g., aluminum alloy). In other words, the sensor mount 1 provides electromagnetic (magnetic flux) shielding.

Also, the sensor mount 1 is fixed to the base 3 by screws and the like (not shown) for fastening the sensor mount to the base 3. That is, the sensor mount 1 is fixed to the base 3 with the sensor mount 1 being in tight contact with the base.

The cover 4 is arranged to cover the sensor mount 1, and has at least one opening 4d, as shown in FIG. 1. Specifically, the cover 4 has a box shape for accommodating the sensor mount 1. The cover 4 is opened on its Z2 side. Specifically, the sensor mount 1 is accommodated in accommodation space defined by the cover 4 and the base 3. In other words, the cover 4, the base 3 and the connectors 8 cover the sensor mount 1 so that the sensor mount 1 is not exposed. Here, the sensor mount 1 may be covered by the cover 4 without the cut-out parts 4c, which will be described later, and the base 3 so that the sensor mount 1 is not exposed.

The cover 4 is formed of metal. Specifically, the cover 4 is formed of a non-magnetic metal (e.g., aluminum alloy). In other words, the cover 4 provides electromagnetic (magnetic flux) shielding.

The cover 4 is fastened to the base 3. Specifically, a flange 4a to be in surface contact with the base 3 is included on an end of the cover 4 on a base 3 side (Z2 side). The cover 4 is fixed to the base 3 by fastening the flange 4a to the base 3 by using screws 4b and the like. In other words, the interior space for accommodating the gyroscopes 2, the sensor mount 1, the power supply board 5 and the control boards 6 are defined by the cover 4 and the base 3 by fixing the cover to the base with the opening 4d of the cover 4 facing the base 3. Also, the cover 4 has two cut-out parts 4c to expose the two connectors 8. Also, the sensor apparatus 100 is attached to another device 200 with a bottom surface of the base 3 (a surface on the Z2 side) being in tight contact with the another apparatus 200. Also, gaskets for interrupting electromagnetic noise are arranged on boundaries between the connectors 8 and the cut-out parts 4c of the cover 4. The gaskets are formed of an electrically conductive material.

Also, the sensor apparatus 100 includes a pair of sensor sets 10. The sensor sets 10 include the gyroscopes 2, acceleration sensors 9, power supply circuits 5b, and the control boards 6 (control circuits 6b). The pair of sensor sets 10 have the same configuration as each other. The pair of sensor sets 10 are arranged side by side in a Y direction.

Each of the pair of sensor sets 10 (see FIG. 1) includes a control board set including the X-axis control board 6x, the Y-axis control board 6y, and the Z-axis control board 6z. In each control board set, the X-axis control board 6x and the Y-axis control board 6y are connected to each other by the wiring part 6a, and the Z-axis control board 6z and the Y-axis control board 6y are connected to each other by the wiring part 6a.

In this embodiment, a pair of X-axis control boards 6x are attached to the pair of X-axis surfaces 1x of the sensor mount 1. The X-axis control boards 6x are directly attached to the X-axis protrusions 1d on the X-axis surfaces 1x. The X-axis control boards 6x are attached to the X-axis protrusions 1d by the screws 20.

The X-axis control board 6x for an X1 side is arranged in a Y1-side part of the X-axis surface 1x on the X1 side. The X-axis control board 6x for an X2 side is arranged in a Y2-side part of the X-axis surface 1x on the X2 side.

In this embodiment, a pair of Y-axis control boards 6y are attached to the pair of Y-axis surfaces 1y of the sensor mount 1. The Y-axis control boards 6y are directly attached to the Y-axis protrusions 1a on the Y-axis surfaces 1y. The Y-axis control boards 6y are attached to the Y-axis protrusions 1a by the screws 20.

In this embodiment, the Z-axis control boards 6z in the pair of sensor sets 10 are attached to the Z-axis surface 1z on the Z1 side in the pair of Z-axis surfaces 1z of the sensor mount 1. The two Z-axis control boards 6z attached to the Z-axis surface 1z are arranged side-by-side in the Y direction. The two Z-axis control boards 6z are arranged adjacent to each other in the Z-axis surface 1z. The Z-axis control boards 6z are directly attached to the Z-axis protrusions 1c on the Z-axis surface 1z. The Z-axis control boards 6z are attached to the Z-axis protrusions 1c by the screws 20.

In this embodiment, each Z-axis control board 6z includes a multi-layer board including at least a wiring pattern 61 or through-holes 62. Holes 63 for attachment of the Z-axis control board to the crest surfaces S1 of the Z-axis protrusions 1c are arranged at positions in the Z-axis control board 6z each of which avoids at least the wiring pattern 61 or the through-hole 62. Specifically, both the wiring pattern 61 and the through-holes 62 are included, and the holes 63 are arranged to avoid both the wiring pattern 61 and the through-holes 62. For example, the through-holes 62 are arranged in an area other than outer edges of the Z-axis control board 6z. The holes 63 are arranged in the outer edges of the Z-axis control board 6z to avoid the through-holes 62. Here, the through-holes 62 serve to connect different layers to each other in the multilayer board. The holes 63 are examples of “attachment parts” in the claims.

In this embodiment, the Z-axis control board 6z has a grounding pattern 64 that is electrically connected to the sensor mount 1 to have a common potential to the sensor mount 1. The holes 63 of the Z-axis control board 6z are arranged in a part of the Z-axis control board 6z on which the grounding pattern 64 is arranged. The grounding pattern 64 is called an FG (frame ground) pattern. The grounding pattern 64 is arranged to extend along the outer edges of the Z-axis control board 6z, for example. The holes 63 are arranged in the outer edges of the Z-axis control board 6z. When the Z-axis control board 6z is attached to the Z-axis protrusions 1c by the screws 20, the grounding pattern 64 and the sensor mount 1 have the same potential.

Although not illustrated in FIG. 2, each of the X-axis control boards 6x and the Y-axis control boards 6y includes the wiring pattern 61, through holes 62 and the grounding pattern 64.

In this embodiment, the Z-axis control board 6z includes cut-out parts 65 avoiding the Z-axis protrusions 1b, as shown in FIG. 2. The cut-out parts 65 are arranged in the outer edges of the Z-axis control board 6z. The Z-axis control board 6z can be attached to the Z-axis protrusions 1c while preventing interference between the Z-axis control board 6z and the Z-axis protrusions 1b by forming the cut-out parts 65 in the Z-axis control board 6z. Also, the cut-out parts 65 have a rectangular shape corresponding to a shape of the Z-axis protrusion 1b as viewed in the Z direction.

In addition, the control board 6 includes a microcontroller, a power supply, and the like (not shown). The control board 6 also includes an acceleration sensor 9. Here, in FIG. 2, each acceleration sensor 9 is schematically shown.

In this embodiment, the power supply board 5 is arranged to be stacked above the Z-axis control boards 6z. The power supply board 5 is stacked above the pair of Z-axis control boards 6z, which are arranged adjacent to each other in the Z-axis surface 1z. The power supply board 5 is directly attached to the sensor mount 1. The power supply board 5 is directly attached to the Z-axis protrusions 1b. The power supply board 5 is attached to the Z-axis protrusions 1b by the screws 20.

The power supply board 5 is arranged to cover the two Z-axis control boards 6z on the Z1 side. The power supply board 5 is connected to the control boards 6 (the pair of Y-axis control boards 6y) by wiring parts 5a. Specifically, the power supply board 5 includes power supply circuits 5b (see FIG. 5) for supplying power to the control circuits 6b (see FIG. 5) included in the control boards 6 through the wiring parts 5a. The power circuits 5b also supply power to the gyroscopes 2 and acceleration sensors 9. Each of the sensor sets 10 includes the power circuit 5b and the control circuit 6b. Also, each control circuit 6b receives information (detection values) from its corresponding gyroscopes 2, its corresponding acceleration sensor 9, and the like.

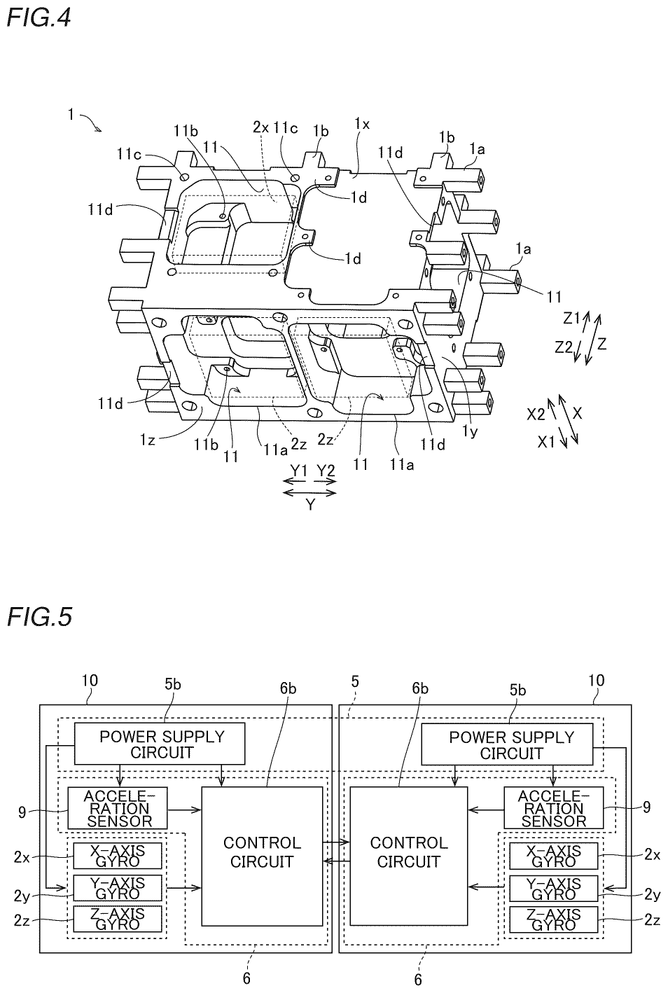

The plurality of gyroscopes 2 are arranged on the sensor mount 1 as shown in FIG. 3. The sensor mount 1 includes a plurality of recessed parts 11 in which the plurality of gyroscopes 2 are arranged. Specifically, the recessed parts 11 are arranged in the pair of X-axis surfaces 1x, the pair of Y-axis surfaces 1y, and the Z-axis surface 1z on the Z2 side of the sensor mount 1. Each of the pairs of X-axis surfaces 1x has one recessed part 11. Also, each of the pairs of Y-axis surfaces 1y has one recessed part 11. Also, the Z-axis surface 1z on the Z2 side has two recessed parts 11 as shown in FIG. 4. The two recessed parts 11 in the Z-axis surface 1z are arranged side by side in the Y direction (see FIG. 4).

Each of the plurality of gyroscopes 2 is accommodated in corresponding one of the recessed parts 11. Specifically, the gyroscope 2 is accommodated in the recessed part 11 not to protrude from an opened end 11a of the recessed part 11.

Also, the gyroscope 2 is fixedly arranged in the recessed part 11 by screwing screws 2a provided in four corners of the gyroscope 2 to screw insertion holes 11b arranged in the recessed part 11.

The gyroscopes 2 include X-axis gyroscopes 2x, Y-axis gyroscopes 2y and Z-axis gyroscopes 2z corresponding to X, Y and Z axes, which are perpendicular to each other. The gyroscopes include two X-axis gyroscopes 2x, two Y-axis gyroscopes 2y and two Z-axis gyroscopes 2z. That is, the gyroscopes include the pair of sensor sets 10 each of which includes the X-axis gyroscope 2x, the Y-axis gyroscope 2y and the Z-axis gyroscope 2z. Here, one of the pair of sensor sets 10 is provided as a backup (redundant) set of sensors for another sensor set 10. Also, the X-axis gyroscopes 2x are examples of a “second axis sensor” in the claims. Also, the Y-axis gyroscopes 2y are examples of a “third axis sensor” in the claims. Also, the Z-axis gyroscopes 2z are examples of a “first axis sensor” in the claims.

Also, the pair of sensor sets 10 are arranged on the common sensor mount 1. That is, the sensor apparatus 100 includes the single sensor mount 1 on which the pair of sensor sets 10 are commonly arranged.

The pair of X-axis gyroscopes 2x are arranged rotational symmetric to each other with respect to an axis line a that passes through a center of gravity of the sensor mount 1 and extends in the Z axis; the pair of Y-axis gyroscopes 2y are arranged rotational symmetric to each other with respect to the axis line α; and the pair of Z-axis gyroscopes 2z are arranged rotational symmetric to each other with respect to the axis line α. As a result, absolute values of detection values of each pair of sensors in the sensor sets 10 become the same as each other. For this reason, it is not necessary to provide an interface board for performing calculation based on the detection values of each pair of sensors in the sensor sets 10. Here, the sensor mount 1 has a rotational symmetric shape, which is rotational symmetric with respect to the axis line a. Note that “rotational symmetric” refers to a broad sense that includes not only perfect rotational symmetry but also rotational symmetry with small errors that bring the absolute values of the detection values of each pair of sensors in the sensor sets 10 in the same range. In other words, the pair of X-axis gyroscopes 2x, the pair of Y-axis gyroscopes 2y or the pair of Z-axis gyroscopes 2z may be arranged rotational asymmetric with respect to the axis line α in the sensor mount 1, which has the rotational symmetric shape with respect to the axis line α, as long as the rotational asymmetry affects the detection values of each pair of sensors in the sensor sets 10.

In detailed description, the pair of X-axis gyroscopes 2x are arranged at the same height position as each other in the Z direction. Also, the pair of X-axis gyroscopes 2x are offset from each other in the Y direction. Specifically, the X-axis gyroscope 2x on the X1 side is arranged in the recessed part 11 that is located in the Y2-side part of the X-axis surface 1x on the X1 side. Also, X-axis gyroscope 2x on the X2 side is arranged in the recessed part 11 that is located in the Y1 -side part of the X-axis surface 1x on the X2 side.

Also, the pair of Y-axis gyroscopes 2y are arranged at the same height position as each other in the Z direction. Also, the pair of Y-axis gyroscopes 2y are offset from each other in the X direction. Specifically, the Y-axis gyroscope 2y on the Y1 side is arranged in the recessed part 11 that is located in the X1 -side part of the Y-axis surface 1y on the Y1 side. The Y-axis gyroscope 2y on the Y2 side is arranged in the recessed part 11 that is located in the X2-side part of the Y-axis surface 1y on the Y2 side.

Also, the pair of Z-axis gyroscopes 2z are arranged at the same height position as each other in the Z direction. Also, the pair of Z-axis gyroscopes 2z are offset from each other in the X direction. The Z-axis gyroscope 2z on the Y1 side is arranged in the recessed part 11 that is located closer to the X1 side in the Z-axis surface 1z on the Z2 side. The Z-axis gyroscope 2z on the Y2 side is arranged in the recessed part 11 that is located closer to the X2 side in the Z-axis surface 1z on the Z2 side.

Here, since the pair of sensor sets 10 are arranged rotational symmetric to each other, polarity of the detection values of each pair of sensors in the sensor sets 10 are opposite to each other. The control boards 6 (control circuits 6b) adjust the detection values of each pair of sensors in the sensor sets 10 to their positive or negative values. Also, since the pair of sensor sets 10 are arranged rotational symmetric to each other, the pair of control boards 6 can have a common configuration. In other words, the pair of control boards have the common configuration in terms that each of the pair of control boards 6 includes the X-axis control board 6x, the Y-axis control board 6y, and the Z-axis control board 6z.

Also, the pair of X-axis gyroscopes 2x are arranged in the recessed parts 11 in the pair of X-axis surfaces 1x, which are arranged on sides opposite to each other. Also, the pair of Y-axis gyroscopes 2y are arranged in the recessed parts 11 in the pair of Y-axis surfaces 1y, which are arranged on sides opposite to each other. That is, the gyroscopes 2 (2x, 2y) are arranged on their corresponding one of four side surfaces (1x, 1y) of the sensor mount 1.

The Z-axis gyroscopes 2z are arranged in their corresponding one of the two recessed parts 11 in the Z-axis surface 1z on the Z2 side. Here, no recessed part 11 is arranged on the Z-axis surface 1z on the Z1 side.

The plates 7 are arranged between the recessed parts 11 and the cover 4, and are arranged to cover the recessed parts 11 so as not to expose the gyroscopes 2 arranged in the recessed parts 11 of the sensor mount 1. Specifically, the plates 7 are arranged to overlap the entire recessed parts 11. Also, each plate 7 is fixed to the sensor mount 1 by inserting screws 7a arranged in four corners of the plate 7 into screw insertion holes 11c arranged outside corresponding one of recessed parts 11.

Also, the plates 7 provide electromagnetic noise shielding. Specifically, the plates 7 are formed of metal. In detailed description, the plates 7 are formed of a non-magnetic metal (e.g., aluminum).

Also, each plate 7 has a plate-like shape extending in corresponding one of the pair of X-axis surfaces 1x or corresponding one of the pair of Y-axis surfaces 1y of the sensor mount 1. Specifically, each plate 7 is formed in a square shape. The plate 7 is attached to the Y2-side part of the X-axis surface 1x on the X1 side, which is formed in a rectangular shape. Also, the plate 7 is attached to the Y1-side part of the X-axis surface 1x on the X2 side, which is formed in a rectangular shape.

The plates 7 include the X-axis plates 7x covering the recessed parts 11 arranged in the X-axis surfaces 1x, and the Y-axis plates 7y covering the recessed parts 11 arranged in the Y-axis surfaces 1y. The X-axis plates 7x are arranged side by side adjacent to the X-axis control boards 6x in the Y direction without overlapping the X-axis control boards 6x (see FIG. 1). The Y-axis plates 7y are arranged to overlap the Y-axis control boards 6y (see FIGS. 1 and 2).

Each Y-axis plate 7y has a plurality of cut-out parts 7b avoiding the Y-axis protrusions 1a of the sensor mount 1. Each X-axis plate 7x has no cut-out part.

Also, the base 3 (see FIG. 1) is arranged to cover the recessed parts 11 (see FIG. 4) arranged in the Z-axis surface 1z on the Z2 side. Specifically, the base 3 is arranged to cover the entire surface of the Z-axis surface 1z on the Z2 side. That is, the two recessed parts 11 in which the two Z-axis gyroscopes 2z are arranged are covered by the common (single) base 3 in the Z-axis surface 1z.

Also, the base 3 provides electromagnetic noise shielding. Specifically, the base 3 is formed of metal. In detailed description, the base 3 is formed of a non-magnetic metal (e.g., aluminum alloy). That is, the cover 4, the plates 7, the sensor mount 1, and the base 3 are formed of the same material.

Also, a thickness t1 of the base 3 (see FIG. 1) is greater than a thickness t2 of the cover 4 (see FIG. 1). Specifically, the thickness t1 of the base 3 is not smaller than twice (e.g., triple) the thickness t2 of the cover 4.

Also, the thickness t1 of the base 3 (see FIG. 1) is greater than a thickness t3 of the plate 7 (see FIG. 3). Specifically, the thickness t1 of the base 3 is not smaller than twice (e.g., triple) a thickness t3 of the plate 7. Here, no plate for shielding against electromagnetic noise is arranged between the base 3 and the Z-axis gyroscopes 2z. In other words, the base 3 and each Z-axis gyroscope 2z are arranged to face each other without the plate between them. The Z-axis gyroscope 2z is enclosed between each recessed part 11 and the base 3 to shield the Z-axis gyroscope 2z against electromagnetic noise.

The gyroscopes 2 (2x to 2z) include sensor main bodies 2b, and connection wiring parts 2c connecting the sensor main bodies 2b to the control boards 6 (Y-axis control boards 6y). The gyroscopes 2 and the control board 6 (Y-axis control board 6y) that are included in the sensor set 10 common to each other are connected by the connection wiring parts 2c.

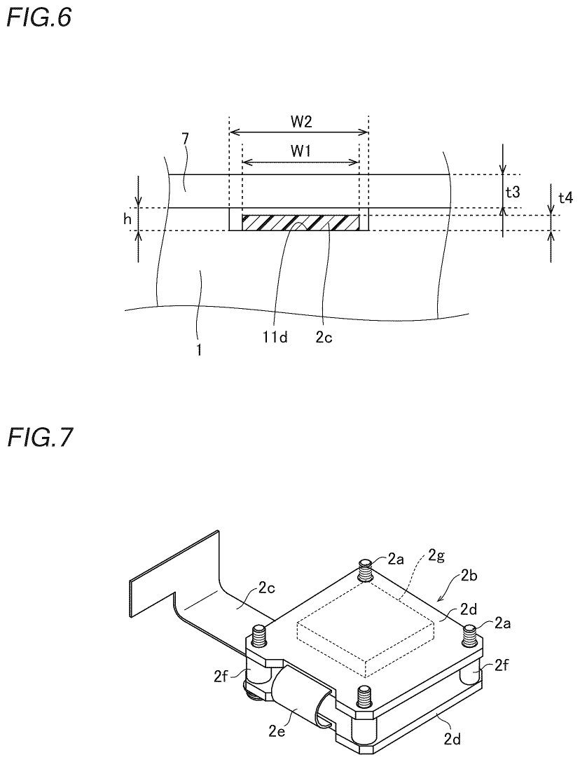

Also, the recessed parts 11 of the sensor mount 1 include cut-out parts 11d through which the connection wiring parts 2c are drawn out. The cut-out parts 11d are arranged in the opened ends 11a of the recessed parts 11. In other words, the connection wiring parts 2c are drawn out through the cut-out parts 11d with recessed part 11 being covered by the plates 7 (base 3) (see FIG. 6). Here, the cut-out parts 11d may be arranged in the plates 7 or in both the recessed parts 11 and the plates 7.

As shown in FIG. 6, the connection wiring parts 2c have the thickness t3 (e.g., 0.8 mm). The cut-out parts 11d have a depth h (e.g., 1 mm) greater than the thickness t3. Also, the connection wiring parts 2c have a width W1. Also, the cut-out parts 11d have a width W2 greater than the width W1. Here, the plurality of cut-out parts 11d have the same size as each other.

Also, the connection wiring parts 2c of the gyroscope 2 include flexible cables. In other words, the connection wiring parts 2c have flexibility (softness). The connection wiring parts 2c are formed of polyimide, for example. The connection wiring parts 2c include flexible cables so that the flexible cables can absorb shock even if vibration occurs. As a result, it is possible to prevent disconnection of the connection wiring parts 2c from the control boards 6. Also, since the connection wiring parts 2c include flexible cables, it is possible to bend the connection wiring parts 2c at an angle that can easily draw out the connection wiring parts in the recessed parts 11 through the cut-out parts 11d. Accordingly, even if a clearance between the cut-out part 11d and connection wiring part 2c is reduced, it is possible to easily draw out the connection wiring part 2c through the cut-out part 11d. Since the aforementioned clearance can be reduced, it is possible to increase a frequency range of electromagnetic noise shielding provided by the plates 7 and the base 3 to a wider range (increase an upper limit on a high frequency side).

The connection wiring parts 2c, which extend from the X-axis gyroscope 2x, the Y-axis gyroscope 2y and the Z-axis gyroscopes 2z in each of the pair of sensor sets 10, are connected to the Y-axis control boards 6y with being bent (deformed).

Also, the gyroscope 2 includes a rigid flexible board, as shown in FIG. 7. The rigid flexible board refers to a board including rigid and flexible parts. The sensor main body 2b includes two rigid parts 2d, and a flexible part 2e connecting the rigid parts 2d to each other. The two rigid parts 2d are arranged to face each other by bending the flexible part 2e. Here, the connection wiring part 2c extends from one of the two rigid parts 2d. Also, the flexible part 2e is formed of the same material (i.e., polyimide) as the connection wiring part 2c.

Also, the sensor main body 2b includes spacers 2f arranged between a pair of rigid parts 2d arranged to face each other. Predetermined space is formed between the two rigid parts 2d by the spacer 2f. The spacers 2f are arranged in four corners of each rectangular (square) rigid part 2d. Also, the spacers 2f have a cylindrical shape. The screws 2a are arranged to pass through the spacers 2f having the cylindrical shape. Dotted lines in FIG. 7 represent a sensor head 2g. The sensor head 2g is an electromagnetic type sensor head using MEMS technology, for example. Also, the sensor head 2g may be a piezoelectric or electrostatic type sensor head.

### Advantages of the Embodiment

In this embodiment, the following advantages are obtained.

In this embodiment, the Z-axis control boards 6z and the power supply board 5 are directly attached to the sensor mount 1 as described above. Accordingly, heat generated from the Z-axis control boards 6z and the power supply board 5 is directly dissipated to the sensor mount 1. Also, the heat dissipated to the sensor mount 1 is dissipated to the another apparatus 200 through the base 3. Consequently, it is possible to easily dissipate the heat generated from the Z-axis control boards 6z and the power supply board 5 even in a case in which the Z-axis control boards 6z and the power supply board 5 are arranged in the cover 4.

Also, similarly to the heat generated from the Z-axis control boards 6z, heat generated from the X-axis control boards 6x and the Y-axis control boards 6y is dissipated to the another apparatus 200 through the sensor mount 1 and the base 3.

In this embodiment, the Z-axis protrusions 1b have a protrusion amount L2 from the Z-axis surface 1z greater than the Z-axis protrusions 1c as described above. Accordingly, since the Z-axis control boards 6z are attached to the Z-axis protrusions 1c, which are arranged to protrude from the Z-axis surface 1z, a gap is created between the Z-axis control boards 6z and the Z-axis surface 1z. As a result, it is possible to prevent contact between the Z-axis control boards 6z and the Z-axis surface 1z even when the Z-axis control boards 6z is deformed due to vibration, and the like. Also, since the power supply board 5 is attached to the Z-axis protrusions 1b, which have the protrusion amount L2 greater than the protrusion amount L1 from the Z-axis surface 1z of the Z-axis protrusions 1c, the Z-axis control boards 6z and the power supply board 5 can be easily stacked.

In this embodiment, the Z-axis control board 6z includes the cut-out parts 65 avoiding the Z-axis protrusions 1b, as described above. Accordingly, it is possible avoid interference between the Z-axis control board 6z and the Z-axis protrusions 1b. As a result, it is possible to prevent the sensor apparatus 100 (sensor mount 1) from becoming larger dissimilar to a case in which the Z-axis protrusions 1b are arranged outside the Z-axis control board 6z without the cut-out parts 65.

In this embodiment, as described above, the sensor mount 1 and the Z-axis protrusions 1c are formed of metal; the Z-axis control board 6z includes a multilayer board including at least the wiring pattern 61 or the through-holes 62; and the Z-axis control board 6z includes the holes 63 attached to the crest surfaces S1 of the Z-axis protrusions 1c and arranged at positions avoiding at least the wiring pattern 61 or the through-holes 62. Accordingly, it is possible to prevent a short circuit between the sensor mount 1 and at least the wiring pattern 61 or the through-holes 62.

In this embodiment, as described above, the Z-axis control board 6z includes the grounding pattern 64 electrically connected to the sensor mount 1 to have a common potential to the sensor mount 1; and the holes 63 of the Z-axis control board 6z are arranged in parts of the Z-axis control board 6z in which the grounding pattern 64 is arranged. Accordingly, since both the sensor mount 1 and the grounding pattern 64 are metal, it is possible to efficiently dissipate heat from the Z-axis control board 6z to the sensor mount 1.

In this embodiment, as described above, the power supply board 5 is arranged to be stacked above the Z-axis control boards 6z. As a result, it is possible to prevent the sensor apparatus 100 from becoming larger dissimilar to a case in which a plurality of power supply boards 5 are provided, and the power supply boards 5 are arranged to be stacked above a plurality of the Z-axis, X-axis and Y-axis boards 6z, 6x and 6y.

In this embodiment, as described above, the power supply board 5 supplies electric power to the Z-axis gyroscopes 2z. Here, the power supply board 5 supplying electric power to the Z-axis gyroscope 2z is likely to be high temperature. For this reason, direct attachment of the power supply board 5 to the sensor mount 1 is particularly effective at preventing a temperature of the power supply board 5, which is likely to be high temperature, from becoming high temperature.

Contact surfaces of the sensor mount 1 and the base 3 are not necessarily entirely in contact with each other. The contact surfaces of the sensor mount 1 and the base 3 may have an area for sufficient heat dissipation to a degree that allows the sensor apparatus 100 to properly function even when the sensor apparatus itself generates heat. The same goes for contact between the sensor mount 1 and the another apparatus.

In this embodiment, as described above, a plurality of Z-axis protrusions 1c and a plurality of Z-axis protrusions 1b are provided. Consequently, it is possible to attach the Z-axis control boards 6z and the power supply board 5 with being stabilized.

In this embodiment, as described above, the Z-axis protrusions 1c which are arranged to protrude from the Z-axis surface 1z and to which the Z-axis control boards 6z are attached, the X-axis protrusions 1d which are arranged to protrude from the X-axis surface 1x and to which the X-axis control boards 6x are attached, and the Y-axis protrusions 1a which are arranged to protrude from the Y-axis surface 1y and to which the Y-axis control boards 6y are attached are provided. As a result, it is possible to prevent contact between the Z-axis, X-axis and Y-axis boards 6z, 6x and 6y, and the Z-axis, X-axis and Y-axis surfaces 1z, 1x and 1y even when the Z-axis, X-axis and Y-axis boards 6z, 6x and 6y are deformed due to vibration, and the like.

In this embodiment, the power supply board 5 is stacked above the pair of Z-axis control boards 6z, which are arranged adjacent to each other in the Z-axis surface 1z. As a result, it is possible to prevent a configuration of the sensor apparatus 100 from becoming complicated dissimilar to a case in which the power supply board 5 is provided to each of the sensor sets 10, and the power supply boards are attached to surfaces different from each other.

### Modified Embodiments

Note that the embodiment disclosed this time must be considered as illustrative in all points and not restrictive. The scope of the present invention is not shown by the above description of the embodiments but by the scope of claims for patent, and all modifications (modified embodiments) within the meaning and scope equivalent to the scope of claims for patent are further included.

While the example in which the Z-axis control boards 6z are used as the “first board” according to the present invention, and the power supply board 5 is used as the “second board” according to the present invention has been shown in the aforementioned embodiment, the present invention is not limited to this. For example, a board other than the Z-axis control board 6z may be used as the “first board” according to the present invention, and a board other than the power supply board 5 may be used as the “second board” according to the present invention.

While the example in which the Z-axis control boards 6z are attached to the Z-axis protrusions 1c has been shown in the aforementioned embodiment, the present invention is not limited to this. For example, the Z-axis control board 6z may be attached to a surface of the Z-axis surface 1z without the Z-axis protrusions 1c.

While the example in which the Z-axis protrusions 1b have a prism shape has been shown in the aforementioned embodiment, the present invention is not limited to this. For example, the Z-axis protrusions 1b may have a cylindrical shape.

Also, instead of the Z-axis protrusions 1b and Z-axis protrusions 1c, one or more protrusions may be arranged on a surface of the sensor mount 1 not to fix and support the Z-axis control boards 6z and the power supply board 5 but to be in contact with surfaces or interiors of the Z-axis control boards 6z and the power supply board 5 so as to absorb heat generated from the Z-axis control boards 6z and the power supply board 5. Also, the base 3 may have a part that directly support both the Z-axis control boards 6z and the power supply board 5 overlying the Z-axis control boards, and directly absorbing heat from the Z-axis control boards 6z and the power supply board 5. Also, parts may be included which fasten the Z-axis control boards 6z and the power supply board 5 to the protrusions via spacers and support them on the protrusions.

While the example in which a plurality of Z-axis protrusions 1c and a plurality of Z-axis protrusions 1b are provided has been shown in the aforementioned embodiment, the present invention is not limited to this. For example, one Z-axis protrusion 1c and one Z-axis protrusion 1b may be provided.

Also, other parts that do not interfere with transfer of heat generated from the Z-axis control boards 6z and the power supply board 5 to the another apparatus may be arranged between the Z-axis control boards 6z and the Z-axis protrusions 1b, between the power supply board 5 and the Z-axis protrusions 1c, between the sensor mount 1 and the base 3, and between the base 3 and the another apparatus.

While the example in which the sensor mount 1 is constructed of a single part, and the base 3 is constructed of a single part has been shown in the aforementioned embodiment, the present invention is not limited to this. The sensor mount 1 may be constructed of two or more parts, and the base 3 may be constructed of two or more parts. Alternatively, the sensor mount 1 and the base 3 may be integrally formed with each other.

Although the sensor mount 1 and the base 3 are constructed of separate parts based on one or more functions assigned to each of the sensor mount 1 and the base 3 in the aforementioned embodiment, it is only required to carry out all of functions stated in the claims with the sensor mount and the base being assembled, and it is not required for each part to carry out its function. Also, the sensor mount 1 and the base 3 may transfer, exchange or share some of the functions stated in the claims between them.

While the example in which each Z-axis control board 6z includes a multi-layer board having the through-holes 62 has been shown in the aforementioned embodiment, the present invention is not limited to this. For example, the Z-axis control board 6z may include a single-layer board.

While the example in which the holes 63 of the Z-axis control board 6z are arranged in a part of the Z-axis control board 6z on which the grounding pattern 64 is arranged has been shown in the aforementioned embodiment, the present invention is not limited to this. For example, the hole 63 may be arranged in a part of the Z-axis control board 6z other than the part on which the grounding pattern 64 is arranged.

While the example in which the Z-axis control board 6z includes the cut-out parts 65 avoiding the Z-axis protrusions 1b has been shown in the aforementioned embodiment, the present invention is not limited to this. For example, the Z-axis control board 6z may have a hole through which the Z-axis protrusion 1b passes. Also, the Z-axis protrusion 1b may be arranged outside the Z-axis control board 6z without the cut-out parts 65 in the Z-axis control board 6z.

While the example in which the power supply board 5 is arranged to be stacked above the Z-axis control boards 6z has been shown in the aforementioned embodiment, the present invention is not limited to this. For example, the power supply board 5 may be arranged to be stacked above the X-axis control board 6x or the Y-axis control board 6y.

While the example in which the gyroscopes include the pair of sensor sets 10 each of which includes a set of the X-axis gyroscope 2x, the Y-axis gyroscope 2y and the Z-axis gyroscope 2z has been shown in the aforementioned embodiment, the present invention is not limited to this. For example, only one sensor set 10, or three or more sensors may be provided.

While the example in which the gyroscope 2 (sensor) is arranged in the recessed part 11 of the sensor mount 1 (sensor arrangement part) has been shown in the aforementioned embodiment, the present invention is not limited to this. For example, a sensor (e.g., an acceleration sensor 9 or a temperature sensor) other than the gyroscope may be arranged in the recessed part 11.

### DESCRIPTION OF REFERENCE NUMERALS

1; sensor mount (sensor arrangement part)
1b; Z-axis protrusion (second protrusion)
1c; Z-axis protrusion (first protrusion)
1z; Z-axis surface (predetermined surface)
2; gyroscope (sensor)
5; power supply board (second board)
4; cover (shielding cover)
4d; opening
6z; Z-axis control board (first board)
61; wiring pattern
62; through hole
63; hole (attachment part)
64; grounding pattern
65; cut-out part
100; sensor apparatus
200; another apparatus
L1; protrusion amount (of first protrusion)
L2; protrusion amount (of second protrusion)
S1; crest surface (first crest surface)
S2; crest surface (second crest surface)

1. A sensor apparatus comprising:
a sensor;
a sensor arrangement part in which the sensor is arranged;
a first board provided to the sensor arrangement part;
a second board arranged parallel to the first board to be stacked above the first board;
a shielding cover provided to cover the sensor arrangement part and including at least one opening; and
a base being in tight contact with the sensor arrangement part and fixing the sensor arrangement part, wherein
the first board and the second board are directly attached to the sensor arrangement part,
an interior space accommodating the sensor, the sensor arrangement part, the first board and the second board is defined by the shielding cover and the base by fixing the shielding cover to the base with the opening of the shielding cover facing the base, and
the sensor apparatus is attached to another apparatus with a bottom of the base being in tight contact with the another apparatus.

2. The sensor apparatus according to claim 1, wherein the sensor arrangement part includes
a predetermined surface,
a plurality of first protrusions that are arranged to protrude from the predetermined surface and to which the first board is attached, and
a plurality of second protrusions that are arranged to protrude from the predetermined surface and to which the second board is attached; and
first crest surfaces are formed on crests of the plurality of first protrusions to be in contact with the first board;
the first crest surfaces are independent of each other;
second crest surfaces are formed on crests of the plurality of second protrusions to be in contact with the second board;
the second crest surfaces are independent of each other;
the first crest surfaces and the second crest surfaces are parallel to the predetermined surface, and are parallel to each other; and
the second protrusions have a protrusion amount from the predetermined surface greater than the first protrusions.

3. The sensor apparatus according to claim 2, wherein the first board includes cut-out parts avoiding the second protrusions.

4. The sensor apparatus according to claim 3, wherein
the sensor arrangement part and the first protrusion comprises metal;
the first board includes a multilayer board including at least a wiring pattern or a through hole; and
the first board includes attachment parts that are attached to the first crest surfaces of the first protrusions and arranged at positions avoiding at least the wiring pattern or the through-hole.

5. The sensor apparatus according to claim 4, wherein
the first board including a grounding pattern electrically connected to the sensor arrangement part to have a common potential to the sensor arrangement part; and
the attachment parts of the first board are arranged in parts of the first board in which the grounding pattern is arranged.
